(19) United States
(12) Patent Application Publication
(10) Pub. No.: US 2016/0319129 A1
(43) Pub. Date: Nov. 3, 2016

(54) VINYL-CAPPED POLY(PHENYLENE) ETHER AND STYRENE-BUTADIENE COPOLYMER BLENDS FOR CURABLE COMPOSITIONS

(71) Applicant: BLUE CUBE IP LLC, Midland, MI (US)

(72) Inventors: Xiaomei Song, Shanghai (CN); Hongyu Chen, Shanghai (CN); Tianhui Xiao, Shanghai (CN); Yonghua Gong, Shanghai (CN); Michael J. Mullins, Houston, TX (US)

(73) Assignee: Blue Cube IP LLC, Midland, MI (US)

(21) Appl. No.: 15/105,301

(22) PCT Filed: Dec. 17, 2014
(86) PCT No.: PCT/US2014/070926

§ 371 Date: Jun. 16, 2016

(30) Foreign Application Priority Data
Dec. 19, 2013 (CN) PCT/CN2013/090010

(51) Int. Cl. C08L 71/12; H05K 1/03; C08L 25/10; C09D 125/10; C09D 171/12; C08J 5/24

(52) U.S. Cl. CPC C08L 71/126; C09D 171/12; C08J 5/24; C08L 25/10; C09D 125/10; H05K 1/0373; C08J 2309/06; C08J 2371/12; C08J 2409/06; C08J 2471/12; C08L 2201/02; C08L 2203/20; H05K 2201/012

(57) ABSTRACT

A composition comprising: a) a vinyl poly(phenylene) ether; b) a styrene-butadiene copolymer; c) optionally a vinyl-benzyl ether of napthol novolac; and d) a free radical initiator, a method for making the composition, and end uses for the composition are disclosed.

### BACKGROUND OF THE INVENTION

1. Field of the Invention

Embodiments of the present disclosure relate to curable compositions and in particular to curable compositions that include polymers and a method of producing the curable compositions.

2. Introduction

Curable compositions are compositions that include thermosettable monomers that can be crosslinked. Crosslinking, also referred to as curing, converts the curable compositions into crosslinked polymers (ie., a cured product) useful in various fields such as, for example, composites, electrical laminates and coatings. Some properties of curable compositions and crosslinked polymers that can be considered for particular applications include mechanical properties, thermal properties, electrical properties, optical properties, processing properties, among other physical properties.

For example, glass transition temperature, dielectric constant and dissipation factor can be properties that are considered to be highly relevant for curable compositions used in electrical laminates. For example, having a sufficiently high glass transition temperature for an electrical laminate can be very important in allowing the electrical laminate to be effectively used in high temperature environments. Similarly, decreasing the dielectric constant and dissipation factor of the electrical laminate can assist in separating a current carrying area from other areas.

To achieve desirable changes in glass transition temperature (Tg), dielectric constant (Dk) and dissipation factor (Df), previous approaches have added various materials to curable compositions. Polybutadiene (PB) has been used to make low Dk/Df laminates due to its outstanding dielectric performance and a fully cured material has relatively good thermal resistance. However, PB based prepregs normally have issues with stickiness and the material is highly flammable. Also, the cured material has a Tg lower than 150° C., and it appeared as a wide Tg peak in a DMTA curve, which may be due to the resin was not fully cured. Styrene-butadiene copolymer (SBC) can be also be used for low Dk/Df laminates. However, it can encounter similar issues. Vinyl capped polyphenylene ether (PPO) is also being developed for low Dk/Df laminates. The cured PPO has high Tg and good flame retardant performance. However, the Dk and Df of the cured product are not as good as those of butadiene based systems. Therefore, an affordable electrical laminate with desirable thermal properties and electrical properties would be beneficial.

### SUMMARY

One broad aspect of the present invention comprises, consists of, or consists essentially of a) a vinyl poly(phenylene) ether; b) a styrene-butadiene copolymer; c) optionally a vinyl-benzyl ether of napthol novolac and d) a free radical initiator.

### DETAILED DESCRIPTION

The composition contains a vinyl poly(phenylene) ether (vinyl PPO). This resin contains one or more vinyl end groups. Examples of vinyl PPOs that can be used in the present invention include, but are not limited to SA9000 SABIC PPO and OPE-2St MGC PPO.

The vinyl PPO is generally present in the range of from about 1 weight percent to 99 weight percent, is present in the range of from 25 weight percent to 75 weight percent in another embodiment and is present in the range of from 30 weight percent to 60 weight percent in yet another embodiment, based on the total weight of the composition.

The vinyl PPO generally has a number average molecular weight (Mn) in the range of from 300 to 25000, has a Mn in the range of from 800 to 10000 in another embodiment, and has a Mn in the range of from 1500 to 4000 in yet another embodiment.

The composition also contains styrene-butadiene copolymer. In an embodiment, the styrene-butadiene copolymer can contain over 50% 1,2-vinyl groups and in the range of from 17 to 27% styrene.

The styrene-butadiene copolymer is generally present in the range of from 40 weight percent to 75 weight percent and is present in the range of from 50 weight percent to 70 weight percent in another embodiment, based on the total weight of the composition. If the styrene-butadiene copolymer content is less than 40 weight percent, the Df will not improve significantly and if it is greater than 70 weight percent, it will induce low glass transition temperature (Tg).

The styrene-butadiene copolymer generally contains from 1 weight percent to 99 weight percent styrene, contains from 10 weight percent to 50 weight percent styrene in another embodiment, and contains 15 to 30 weight percent styrene in yet another embodiment.

The styrene-butadiene copolymer generally contains from 30 weight percent to 85 weight percent 1,2-vinyl groups and contains 50 to 70 weight percent 1,2-vinyl groups in another embodiment. If the 1,2-vinyl group content is less than 30 weight percent, it will induce low Tg or phase separation.

The styrene-butadiene copolymer generally has a number average molecular weight in the range of from 500 to 8000. If the molecular weight of styrene-butadiene copolymer is larger than 8000, it will induce phase separation.

In an embodiment, the composition also includes a vinyl benzyl ether of napthol novolac (VNPN). The VNPN is optional. VNPN can be synthesized by reacting napthol novolac (NPN) with vinyl benzyl chloride (VBC) as depicted below:

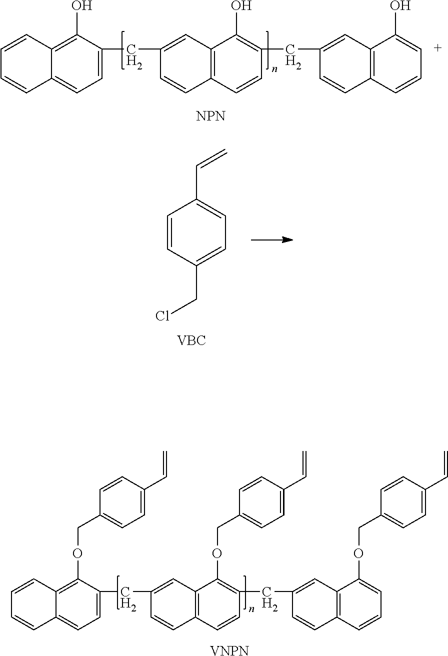

The vinyl-benzyl ether of napthol novolac generally has a number average molecular weight of from 400 to 1500 and has a hydroxyl group content of less than 1 weight percent, based on the total weight of the vinyl-benzyl ether of naphthol novolac.

Vinyl benzyl ethers of napthol novolac are generally present in the range of from about 0 weight percent to 99 weight percent, are present in the range of from 25 weight percent to 75 weight percent in another embodiment and are present in the range of from 30 weight percent to 60 weight percent in yet another embodiment, based on the total weight of the composition.

The composition also includes a free radical initiator to promote a free radical reaction. Examples of free radical initiators include but are not limited to dialkyldiazenes (AIBN), diaroyl peroxides (BPO), dicumyl peroxide (DCP), cumene hydroperoxide (CHP), tert-butyl hydroperoxide (tBHP), and disulfides. Commercial examples of free radical initiators that can be used in the present invention include, but are not limited to Luperox-F40P and Luperox-101 from Arkema Company.

Such initiators can be used alone and in combination to determine the on-set initiating temperature of the free radical reaction. The free radical initiator is generally present in the range of from about 0.01 weight percent to 10 weight percent, is present in the range of from 0.1 weight percent to 8 weight percent in another embodiment and is present in the range of from 2 weight percent to 5 weight percent in yet another embodiment, based on the total weight of the composition.

The composition can also contain a flame retardant. Examples of flame retardants that can be used include but are not limited to brominated or non-brominated resins, brominated additives, non-brominated additives, and phosphorous based flame retardant agents.

The flame retardant is generally present in the range of from about 0 weight percent to 99 weight percent, is present in the range of from 0 weight percent to 70 weight percent in another embodiment and is present in the range of from 5 weight percent to 60 weight percent in yet another embodiment, based on the total weight of the composition.

Fillers can optionally be present in the composition. Examples include but are not limited to silica, talc, aluminum trihydrate (ATH), and magnesium hydroxide.

Fillers can be generally present in the range of from about 0 weight percent to 80 weight percent, can be present in the range of from 1 weight percent to 50 weight percent in another embodiment and can be present in the range of from 1 weight percent to 30 weight percent in yet another embodiment, based on the total weight of the composition.

The composition can also contain optionally one or more solvents. Examples of solvents include but are not limited to methyl ethyl ketone (MEK), dimethylformamide (DMF), ethyl alcohol (EtOH), propylene glycol methyl ether (PM), propylene glycol methyl ether acetate (DOWANOL™ PMA) and mixtures thereof.

Solvents can be generally present in the range of from about 0 weight percent to 60 weight percent, can be present in the range of from 1 weight percent to 50 weight percent in another embodiment and can be present in the range of from 30 weight percent to 40 weight percent in yet another embodiment, based on the total weight of the composition.

The composition can be prepared by any suitable method known by those skilled in the art. In an embodiment, a styrene-butadiene copolymer solution is admixed with a vinyl PPO solution. A flame retardant and initiator are also added, along with any other desired components, such as fillers. In an embodiment, a vinyl-benzyl ether of napthol novolac is also added.

In another embodiment of the present invention there is disclosed a method for preparing a prepreg comprising a) admixing the composition described above with a solvent to form a varnish; b) incorporating the varnish onto a substrate to form a coated substrate; and c) drying the coated substrate at a drying temperature in the range of from 130° C. to 160° C. for an amount of time in the range of from 2 minutes to 6 minutes to form a prepreg.

The varnish can be incorporated onto the substrate by any suitable method. Examples include but are not limited to rolling, dipping, spraying, brushing and/or combinations thereof. The substrate is typically a woven or nonwoven fiber mat containing, for instance, glass fibers or paper.

The coated substrate is “B-staged” by heating at a temperature sufficient to draw off solvent in the formulation and optionally to partially cure the formulation, so that the coated substrate can be handled easily. The “B-staging” step is usually carried out at a temperature of from 90° C. to 210° C. and for a time of from 1 minute to 15 minutes. In an embodiment, the coated substrate is dried at a temperature in the range of from 130° C. to 160° C. and is dried for an amount of time in the range of from 2 minutes to 6 minutes.

The substrate that results from B-staging is called a “prepreg.” One or more sheets of prepreg are stacked or laid up in alternating layers with one or more sheets of a conductive material, such as copper foil, if an electrical laminate is desired.

The laid-up sheets are pressed at high temperature and pressure for a time sufficient to cure the resin and form a laminate. The temperature of this lamination step is usually between 100° C. and 230° C., and is most often between 165° C. and 190° C. The lamination step may also be carried out in two or more stages, such as a first stage between 100° C. and 150° C. and a second stage at between 165° C. and 190° C. The pressure is usually between 50 N/cm² and 500 N/cm². The lamination step is usually carried out for a time of from 1 minute to 200 minutes, and most often for 45 minutes to 90 minutes. The lamination step may optionally be carried out at higher temperatures for shorter times (such as in continuous lamination processes) or for longer times at lower temperatures (such as in low energy press processes).

Optionally, the resulting laminate, for example, a copper-clad laminate, may be post-treated by heating for a time at high temperature and ambient pressure. The temperature of post-treatment is usually between 120° C. and 250° C. The post-treatment time usually is between 30 minutes and 12 hours.

### EXAMPLES

The following materials were used in the Examples below:
Ricon® 100 resin (styrene butadiene random copolymer with about 70% 1,2 vinyl and 17-27% styrene) from Sartomer
Ricon® 181 resin (styrene butadiene random copolymer with about 30% 1,2 vinyl and 25-35% styrene, average Mn: 3000-3500) from Sartomer
Ricon® 184 resin (styrene butadiene random copolymer with about 30% 1,2 vinyl and 25-35% styrene, average Mn: 8000-9000) from Sartomer

SA9000 (Vinyl PPO, vinyl-capped Polyphenylene Ether Oligomer (Mn is about 1600)) from SABIC

Self-synthesized V-NPN synthesized with a number average molecular weight of 1045 and average hydroyl value of 67
1,2-Bis(2,3,4,5,6-pentabromophenyl)ethane flame retardant from Unibrum Corp.
DCP (Dicumyl Peroxide), AIBN (dialkyldiazenes), BPO (diaroyl peroxides), TBHP (Tert-butyl hydroperoxide), CHP (Cumene Hydroperoxide) from Sinopharm Chemcial Reagent Co. Ltd.

Preparation

### Examples 1-24 and Comparative Example A

A free radical curing reaction between SBC and vinyl PPO (SA9000) was carried out as follows: SBC resin was dissolved in MEK to make a 50% SBC/MEK solution. Vinyl PPO resin was dissolved in MEK or Xylene or Toluene (according to different formulations) to make a 50% PPO/MEK solution. The two solutions were then mixed together and were mixed with flame retardant 1,2-Bis(2, 3, 4, 5, 6-pentabromophenyl)ethane. Free radical initiators were added to make a homogeneous varnish. The resin formulation was hand-brushed onto 1080# glass fiber fabrics and the solvent was removed in a vacuum oven at different temperatures for various minutes (according to different formulations). Samples were pressed with 8 ply and cured at 220° C. for 2 hours and the properties of the casted samples were tested.

Treater run conditions:

Varnishes were prepared by the procedure as listed above. For the treater run, prepregs were dried at 145° C. with the fabrics speed at 2 m/min. Laminates were pressed with 6 ply of 2116# glass fabrics.

Examples 1-12 were prepared according to the following formulation: 22% Ricon 100®, 22% SA 9000, 18% Bromine flame retardant, 1% DCP, and 37% MEK solvent. listed in Table 1 below and cured at 220° C. for 2 hours. 1080# glass fabrics were used to make hand brushing boards. The properties of these compositions, with different drying times and temperatures, are shown in Table 1, below.

Comparative Example A and Examples 13-17 were prepared according to the formulations listed in Table 2 below and cured at 220° C. for 2 hours. 1080# glass fabrics were used to make hand brushing boards.

Comparative Examples B and C and Examples 18-22 were prepared according to the formulations listed in Table 3 below and cured at 220° C. for 2 hours. 1080# glass fabrics were used to make hand brushing boards.

Examples 23 and 24 were prepared according to the formulations listed in Table 4 below and cured at 220° C. for 2 hours. 2116# glass fabrics were used to make treater run boards.

TABLE 1
Laminate properties with prepregs dried at different temperatures for
different lengths of time

| | Prepreg | Prepreg | | | |
|---|---|---|---|---|---|
| | Drying | Drying | Laminate | Laminate | Laminate |
| | T (° C.) | Time (min) | Tg (° C.) | Df | Dk |
| Example 1 | 120 | 3 | 170 | 0.003 | 2.95 |
| Example 2 | 120 | 5 | 172 | 0.0029 | 2.93 |
| Example 3 | 130 | 3 | 188 | 0.0027 | 3.02 |
| Example 4 | 130 | 5 | 184 | 0.0026 | 3.05 |
| Example 5 | 140 | 3 | 194 | 0.0028 | 2.9 |
| Example 6 | 140 | 5 | 188 | 0.0019 | 2.88 |
| Example 7 | 150 | 3 | 190 | 0.0023 | 3.09 |
| Example 8 | 150 | 5 | 187 | 0.0021 | 2.97 |
| Example 9 | 160 | 3 | 182 | 0.0021 | 2.88 |
| Example 10 | 176 | 3 | 162 | 0.002 | 3.06 |
| Example 11 | 176 | 5 | 160 | 0.002 | 2.95 |
| Example 12 | 180 | 3 | 156 | 0.002 | 3.05 |

As is evident from the table above, the drying temperature is correlated with the Tg of the laminate. The most suitable drying temperature was in the range of from 130° C. to 160° C. (Examples 3-9), while temperatures lower than 130° C. (Examples 1-2) or higher than 160° C. (Examples 10-12) were correlated with reduced Tg of the laminates. A longer drying time can benefit Df, but may not benefit the Tg.

TABLE 2
Formulation, electrical properties and thermal performance
of SBC/PPO laminate with different initiators

| | Comparative | | | | | |
|---|---|---|---|---|---|---|
| | Example A | Example 13 | Example 14 | Example 15 | Example 16 | Example 17 |
| Components | (solid wt/g) | (solid wt/g) | (solid wt/g) | (solid wt/g) | (solid wt/g) | (solid wt/g) |
| SBC | 10 | 10 | 10 | 10 | 10 | 10 |
| Vinyl PPO | 10 | 10 | 10 | 10 | 10 | 10 |
| FR | 8.28 | 8.28 | 8.28 | 8.28 | 8.28 | 8.28 |
| BPO | | 0.4 | | | | |
| CHP | | | 0.4 | | | |
| BTHP | | | | 0.4 | | |
| AIBN | | | | | 0.4 | |
| DCP | | | | | | 0.4 |
| Prepreg dried | 150° C. | 150° C. | 150° C. | 150° C. | 150° C. | 150° C. |
| condition | 3 min | 3 min | 3 min | 3 min | 3 min | 3 min |
| Gel time/s | >10 min | 150 | 240 | 240 | 220 | 240 |
| at 150° C. | | | | | | |
| Resin content/% | 78 | 76 | 75 | 76 | 75 | 75 |
| Br content | 24 | 24 | 24 | 24 | 24 | 24 |
| in resin/% | | | | | | |
| Bake | 220° C. | 220° C. | 220° C. | 220° C. | 220° C. | 220° C. |
| condition | 2 h | 2 h | 2 h | 2 h | 2 h | 2 h |
| Tg/° C. | NA | 152 | 135 | 134 | 185 | 190 |
| (DMA) | | | | | | |
| Dk/1 GHz | NA | 2.69 | 2.92 | 2.84 | 3.56 | 3.63 |
| Df/1 GHz | NA | 0.002 | 0.002 | 0.002 | 0.002 | 0.002 |

As is evident from the Table above, if an initiator was not added, then the gel time exceeded 10 minutes and the boards were not pressed successfully (Comparative Example A). Low and medium-temperature initiators (AIBN in Example 16 and DCP in Example 17) had good initiating efficiency for the SBC/PPO system, but high temperature initiators (BPO in Example 13, CHP in Example 14, and BTHP in Example 15) did not work well in the SBC/PPO system, resulting in low Tg.

TABLE 3
Formulation, thermal performance, Tg, Dk, Df, FR performance and Cu-peel strength of SBC/PPO laminate

| | Comp. | Comp. | | | | | |
|---|---|---|---|---|---|---|---|
| | Example B | Example C | Example 18 | Example 19 | Example 20 | Example 21 | Example 22 |
| Components | (solid wt/g) | (solid wt/g) | (solid wt/g) | (solid wt/g) | (solid wt/g) | (solid wt/g) | (solid wt/g) |
| SBC | 10 (Ricon | 10 (Ricon | 12(Ricon | 11 (Ricon | 10(Ricon | 9(Ricon | 8 (Ricon |
| | 181) | 184) | 100) | 100) | 100) | 100) | 100) |
| Vinyl PPO | 10 | 10 | 8 | 9 | 10 | 11 | 12 |
| FR | 8.28 | 8.28 | 8.28 | 8.28 | 8.28 | 8.28 | 8.28 |
| DCP | 0.4 | 0.4 | 0.4 | 0.4 | 0.4 | 0.4 | 0.4 |
| Gel time/s | 240 | 250 | 240 | 240 | 220 | 240 | 235 |
| (150 C.) | | | | | | | |
| Resin content/% | 76 | 75 | 76 | 75 | 75 | 75 | 75 |
| Br content | 24 | 24 | 24 | 24 | 24 | 24 | 24 |
| in resin/% | | | | | | | |
| Prepreg drying | 150° C. | 150° C. | 150° C. | 150° C. | 150° C. | 150° C. | 150° C. |
| temp. and time | 3 min | 3 min | 3 min | 3 min | 3 min | 3 min | 3 min |
| Bake | 220° C. | 220° C. | 220° C. | 220° C. | 220° C. | 220° C. | 220° C. |
| Condition | 2 h | 2 h | 2 h | 2 h | 2 h | 2 h | 2 h |
| Tg/° C. | 140 | Phase | 170 | 183 | 190 | 196 | 195 |
| (DMA) | | separation | | | | | |
| Dk/1 GHz | 2.82 | NA | 2.76 | 2.91 | 2.96 | 2.85 | 2.75 |
| Df/1 GHz | 0.002 | NA | 0.0024 | 0.0022 | 0.0025 | 0.0026 | 0.0027 |
| Td/° C. | 350 | NA | 360 | 374 | 383 | 365 | 360 |
| T288/min | 50 | NA | >60 | >90 | >90 | 60 | 55 |
| FR Performance | V-0 | NA | V-0 | V-0 | V-0 | V-0 | V-0 |
| (UL-90) | | | | | | | |
| Peel Strength/ | 6.7 | NA | 8.4 | 7.8 | 8.0 | 7.5 | 7.1 |
| (Ib/in) | | | | | | | |

As is evident from the above Table, use of PPO resulted in high Tg, particularly at a high PPO to SBC ratio, although Df increased a little due to higher PPO content (Examples 19-2 2). When the Ricon 100 content was high (Example 18), the Tg decreased. Use of the Ricon 181 resin largely resulted in decreased Tg due to much lower vinyl bonds in the resin (Comparative Example B) and the Ricon 184 resin had a phase separation problem due to its large molecular weight (Comparative Example C). It is also evident that SBC/PPO laminates (with a SBC/PPO ratio of 6/4 to 4/6, Examples 20-24) show good thermal and flame retardant performance as well as good copper peel strength.

TABLE 4
Formulations for treater run and thermal properties, Tg, Dk, Df, FR
performance and Cu-peel strength of laminate

| | Example 23 | Example 24 |
|---|---|---|
| Components | (solid wt/g) | (solid wt/g) |
| PPO/Solvent | 1000 g/ | 1000 g/ |
| | 352 gToluene + | 352 gToluene + |
| | 600 gMEK | 600 gMEK |
| Ricon 100/Solvent | 1000 g/ | 1000 g/935 gMEK + |
| | 935 gMEK + | (560 gMEK + |
| | (560 gMEK + | 140 gToluene) |
| | 140 gToluene) | |
| FR | 791 g (23%) | 791 g (23%) |
| Filler/SiO2 | none | 677 g (20%) |
| Initiator/DCP | 40 g | 40 g |
| Vinyl silane/ | none | 3.4 g |
| (0.5 wt %@SiO2) | | |
| Varnish solid content/% | 60 | 60 |
| Varnish Gel time/s | 260 | 250 |
| (150 C.) | | |
| Prepreg gel time/s (150 C.) | 100 | 100 |
| Prepreg residual solvent/% | 0.2 | 0.18 |
| Prepreg resin content/% | 48% | 54% |
| Prepreg drying temp. and | 145° C. 4 min | 145° C. 4 min |
| time | | |
| Cure protocol: | 220 2 h | 220 2 h |
| Resin content/% | 44 | 50 |
| Br content in resin/% | 23 | 23 |
| Laminate thickness/mm | 0.84 | 1.05 |
| Laminate residual solvent/% | 0.2 | 0.22 |
| Dk @ 1 GHz | 3.54 | 3.54 |
| Df @ 1 GHz | 0.0024 | 0.0027 |
| Tg (DMA)/° C. | 185 | 182 |
| Td/° C. | 406 | 410 |
| T288/min | >90 | >80 |
| FR Performance (UL-90) | V-0 (<1s) | V-0 (<3s) |
| Peel Strength/(lb/in) | >8 | >8 |
| Interlayer adhesive | NA | NA |
| strength/ | | |
| Water absorption (wt. %) | 0.17 | 0.15 |
| Solder dip | Pass | Pass |
| Average CTE/ppm (z-axis, | 103 | 74 |
| below Tg) | | |
| Toughness ranking | Good | Good |

As is evident from the Table above, the average CTE of the laminate with fillers (Example 24) was improved compared with the laminate without fillers (Example 23), due to the movement restriction effect of polymer chains by fillers.

### Examples 25-26 and Comparative Examples D-H

A free radical curing reaction between SBC and vinyl PPO (SA9000) was carried out as follows: SBC resin was dissolved in MEK to make a 50% SBC/MEK solution. Vinyl PPO resin was dissolved in MEK to make a 50% PPO/MEK solution. V-NPN was dissolved in MEK to make a 50% V-NPN/MEK solution. The three solutions were mixed together and mixed with a flame retardant 1,2-Bis(2, 3, 4, 5, 6-pentabromophenyl)ethane. Free radical initiators were added to make a homogeneous varnish. The resin formulation was then hand-brushed onto 1080# glass fiber fabrics and solvent was removed in a vacuum oven at 150° C. for 3 minutes. Samples were pressed with 8 layers and cured at 200° C. for 3 hours and at 250° C. for 1 hour and the properties of the casted samples were tested.

The following board pressing protocol was used: The temperature was increased to 150° C. Force was then exerted with 24000 pounds at 150° C. This was repeated several times in order to exhaust the bubbles. The temperature was then increased from 150° C. to 200° C., and this temperature was kept constant for 3 hours. The temperature was then increased to 250° C., and this was kept constant for 1 hour, after which the temperature was decreased to room temperature.

Comparative Examples D-H and Examples 25-26 were prepared according to the formulations listed in Table 8 and cured at conditions listed in Table 5, below.

TABLE 5
Formulation, electrical properties and thermal performance of SBC/PPO/V-NPN laminates

| | Comp | Comp | Comp | Comp | Comp | | |
|---|---|---|---|---|---|---|---|
| | Example D | Example E | Example F | Example G | Example H | Example 25 | Example 26 |
| Components | (solid wt/g) | (solid wt/g) | (solid wt/g) | (solid wt/g) | (solid wt/g) | (solid wt/g) | (solid wt/g) |
| SBC | 10 | 0 | 0 | 10 | 8 | 8 | 10 |
| Vinyl PPO | 10 | 10 | 0 | 0 | 8 | 8 | 2 |
| V-NPN | | 10 | 20 | 10 | 10 | 4 | 8 |
| FR1 | 8.28 | 8.28 | 8.28 | 8.28 | 8.28 | 8.28 | 8.28 |
| DCP | 0.4 | 0.4 | 0.2 | 0.4 | 0.48 | 0.4 | 0.4 |
| Gel | 220 | 200 | 200 | 240 | 240 | 240 | 260 |
| time(150° C.)/s | | | | | | | |
| Resin content/% | 78 | 76 | 75 | 76 | 75 | 75 | 75 |
| Br content | 24 | 24 | 24 | 24 | 24 | 24 | 24 |
| in resin/% | | | | | | | |
| Bake | 200° C. | 200° C. | 200° C. | 200° C. | 200° C. | 200° C. | 200° C. |
| condition | 3 h + 250° C. | 3 h + 250° C. | 3 h + 250° C. | 3 h + 250° C. | 3 h + 250° C. | 3 h + 250° C. | 3 h + 250° C. |
| | 1 h | 1 h | 1 h | 1 h | 1 h | 1 h | 1 h |
| Tg/° C. | 190 | Phase | 240 | Phase | 205/239 | 212 | 237 |
| (DMA) | | separation | | separation | (Two peaks) | | |
| Dk/1 GHz | 3.01 | NA | 3.21 | NA | 3.51 | 3.00 | 3.15 |
| Df/1 GHz | 0.0025 | NA | 0.008 | NA | 0.0011 | 0.0029 | 0.0030 |
| Td/° C. | 360 | NA | 383 | NA | NA | 362 | 370 |
| T288/min | >60 | NA | >60 | NA | NA | >60 | >60 |
| FR Performance | V-0 | NA | V-0 | NA | V-0 | V-0 | V-0 |
| (UL-90) | | | | | | | |

As is evident from the above table, the SBC/Vinyl PPO blends had a moderate Tg and low Dk and Df (Comparative Example D). Vinyl PPO/V-NPN blends (Comparative Example E) or SBC/V-NPN blends (Comparative Example G) had phase separation problems due to polarity differences between the components. Neat V-NPN (Comparative Example F) can be cured with an initiator and resulted in a high Tg, however, the Df was also as high as 0.008 and the laminate was quite fragile. Through suitable composition adjustment for SBC/Vinyl PPO/V-NPN, the phase separation problem can be avoided and a laminate with high Tg and low Dk, Df was obtained, as shown in Examples 25 and 26. However, if the SBC content was less than 30% of resin in the formulation, there were two Tg peaks shown in DMTA curve, indicating phase separation in the laminate (Comparative Example H). The laminates in Comparative Examples D, F and Examples 25 and 26 all had acceptable Td and T288, and also good flame retardant performance with 24% Br content.

Test Methods

Decomposition temperature (Td) of the cured resins was performed by Thermogravity analysis (TGA) with Instrument TGA Q5000 V3.10 Build 258. The test temperature ranges from room temperature to 700° C. for all the examples and comparative examples; the heating rate is 20° C./min, nitrogen flow protection. The decomposition was determined through selecting the corresponding temperature at 5% of weight loss (residual weight 95%) of materials.

Glass transition temperature (Tg) of the cured resins was determined with RSA III dynamic mechanical thermal analyzer (DMTA). Samples were heated from −50 to 250° C. at 3° C./min heating rate. Test frequency was 6.28 rad/s. The Tg of the cured resin was obtained from the tangent delta peak.

The dielectric constant and dissipation factor (Dk and Df) were determined by ASTM D-150 employing an Agilent E4991A RF impedance/material analyzer under 1 GHz at room temperature. The sample thickness was 0.3˜3.0 millimeters. To obtain a Tier 5 laminate, Df value should be controlled under 0.005.

T288 was measured using a TA instrument TMA Q400 operating at a 10° C./min heating rate and isothermal at 288° C. of an unclad sample of 6.4 mm×6.4 mm. The failure (delamination) of the sample is evidenced by a sudden and rapid indication of expansion in the plot of time vs. Z-dimension.

FR test: The varnish was brushed on 1080# or 2116# glass fabrics and baked in an oven for 3-5 min at various temperatures to obtain prepregs (according to different formulations). The prepreg sheets were molded into a laminate and cured by a regular hot press machine. The final laminate was cut into the standard samples for UL-94 FR testing.

Gel time: The gel time is the amount of time necessary for a resin to meet its gel point (the point at which the resin turns from a viscous liquid to an elastomer). The gel time was measured and recorded using approximately 0.7 ml of liquid dispensed on a hot plate maintained at 176° C., stroking the liquid back and forth after 60 s on the hot-plate until it gelled.

1. A composition comprising:
a) a vinyl poly(phenylene) ether;
b) a styrene-butadiene copolymer;
c) optionally a vinyl-benzyl ether of napthol novolac; and
d) a free radical initiator.

2. A composition in accordance with claim 1 wherein the vinyl poly(phenylene) ether has a number average molecular weight in the range of from 300-5000.

3. A composition according to claim 1, wherein the vinyl-benzyl ether of naphthol novolac has a number average molecular weight of from 400 to 1500 and has a hydroxyl group content of less than 1 weight percent, based on the total weight of the vinyl-benzyl ether of naphthol novolac.

4. A composition according to claim 1, wherein the styrene-butadiene copolymer is present in an amount in the range of from 40 weight percent to 70 weight percent the vinyl(poly)phenyl ether is present in an amount in the range of from 25 weight percent to 75 weight percent, the vinyl-benzyl ether of napthol novolac is present in an amount in the range of from 25 weight percent to 75 weight percent and the initiator is present in the range of from 0.01 weight percent to 10 weight percent, based on the total weight of the composition.

5. A composition according to claim 1, wherein the styrene-butadiene copolymer has a number average molecular weight from 500 to 8000, has a styrene content in the range of from 10 weight percent to 50 weight percent and a 1,2-vinyl group content in the range of from 30 weight percent to 85 weight percent, based on the total weight of the styrene-butadiene copolymer.

6. A composition according to claim 1, further comprising:
e) a flame retardant.

7. A composition according to claim 1, wherein said initiator is selected from the group consisting of dialkyldiazenes, diaroyl peroxides, dicumyl peroxide, tert-butyl hydroperoxide, cumene hydroperoxide, disulfides, and combinations thereof.

8. A composition according to claim 1, further comprising:
f) at least one filler.

9. A method for preparing a prepreg comprising
a) admixing a composition comprising
i) a polyphenyl ether having at least one vinyl end group;
ii) a styrene-butadiene copolymer; and
iii) an initiator; and
iv) a solvent
to form a varnish;
b) incorporating the varnish onto a substrate to form a coated substrate;
c) drying the coated substrate at a drying temperature in the range of from 130° C. to 160° C. for an amount of time in the range of from 2 minutes to 6 minutes to form a prepreg.

10. A method in accordance with claim 9 wherein the composition of step a) further comprises v) a vinyl-benzyl ether of napthol novolac.

11. A prepreg prepared by the method of claim 9.

12. A prepreg prepared by the method of claim 10.

13. An electrical laminate made from the prepreg of claim 11.

14. An electrical laminate made from the prepreg of claim 12.

15. A composition according to claim 1, wherein the styrene-butadiene copolymer has a number average molecular weight from 500 to 8000, has a styrene content in the range of from 10 weight percent to 50 weight percent and a 1,2-vinyl group content in the range of from 30 weight percent to 85 weight percent, based on the total weight of the styrene-butadiene copolymer; and wherein the vinyl-benzyl ether of naphthol novolac has a number average molecular weight of from 400 to 1500 and has a hydroxyl group content of less than 1 weight percent, based on the total weight of the vinyl-benzyl ether of naphthol novolac.

16. A composition according to claim 4, further comprising e) a flame retardant.

17. A composition according to claim 2, wherein said initiator is selected from the group consisting of dialkyldiazenes, diaroyl peroxides, dicumyl peroxide, tert-butyl hydroperoxide, cumene hydroperoxide, disulfides, and combinations thereof.

18. A composition according to claim 16, wherein the vinyl poly(phenylene) ether has a number average molecular weight in the range of from 300-5000; and the vinyl-benzyl ether of naphthol novolac has a number average molecular weight of from 400 to 1500 and has a hydroxyl group content of less than 1 weight percent, based on the total weight of the vinyl-benzyl ether of naphthol novolac.

19. A composition according to claim 8, wherein the styrene-butadiene copolymer has a number average molecular weight from 500 to 8000, has a styrene content in the range of from 10 weight percent to 50 weight percent and a 1,2-vinyl group content in the range of from 30 weight percent to 85 weight percent, based on the total weight of the styrene-butadiene copolymer; and further comprising e) a flame retardant.

20. A composition according to claim 8, further comprising e) a flame retardant.
